(19) United States
(12) Patent Application Publication
(10) Pub. No.: US 2011/0266638 A1
(43) Pub. Date: Nov. 3, 2011

(54) Semiconductor Device Comprising Contact Elements and Metal Silicide Regions Formed in a Common Process Sequence

(75) Inventors: Kai Frohberg, Niederau (DE); Rainer Giedigkeit, Dresden (DE); Robert Binder, Dresden (DE); Stephan Waidmann, Dresden (DE)

(73) Assignee: GLOBALFOUNDRIES INC., Grand Cayman (KY)

(21) Appl. No.: 12/964,020

(22) Filed: Dec. 9, 2010

(30) Foreign Application Priority Data
Apr. 30, 2010 (DE) 10 2010 028 458.0

(51) Int. Cl. H01L 29/423; H01L 21/28

(52) U.S. Cl. 257/412; 438/586; 257/E21.19; 257/E29.127

(57) ABSTRACT

A metal silicide in sophisticated semiconductor devices may be provided in a late manufacturing stage on the basis of contact openings, wherein the deposition of the contact material, such as tungsten, may be efficiently combined with the silicidation process. In this case, the thermally activated deposition process may initiate the formation of a metal silicide in highly doped semiconductor regions.

### BACKGROUND OF THE INVENTION

1. Field of the Invention

The present disclosure generally relates to the fabrication of integrated circuits, and, more particularly, to the fabrication of highly sophisticated field effect transistors, such as MOS transistor structures, requiring contact areas to be formed after providing the interlayer dielectric material of a contact level.

2. Description of the Related Art

The manufacturing process for integrated circuits continues to improve in several ways, driven by the ongoing efforts to scale down the feature sizes of the individual circuit elements. Presently, and in the foreseeable future, the majority of integrated circuits are and will be based on silicon devices, due to the superior availability of silicon substrates and due to the well-established process technology that has been developed over the past decades. A key issue in developing integrated circuits of increased packing density and enhanced performance is the scaling of transistor elements, such as MOS transistor elements, to provide the immense number of transistor elements that may be necessary for producing complex integrated circuits, such as CPUs, memory devices, mixed signal devices and the like. One important aspect in manufacturing field effect transistors having reduced dimensions is the reduction of the length of the gate electrode that controls the current flow in a conductive channel positioned between the source and drain regions of the transistor. The source and drain regions of the transistor element are conductive semiconductor regions including dopants of an inverse conductivity type compared to the dopants in the surrounding crystalline active region, e.g., a substrate or a well region.

Although the reduction of the gate length results in smaller and faster transistor elements, it turns out, however, that a plurality of issues are additionally involved to maintain proper transistor performance for a reduced gate length. One challenging task in this respect is the provision of shallow junction regions, i.e., source and drain extension regions and drain and source regions connecting thereto, which nevertheless exhibit a high conductivity so as to minimize the resistivity in conducting charge carriers from the source via the channel and to the drain region.

By providing sophisticated dopant profiles in the drain and source regions in combination with a reduced channel length, therefore, in total, a reduced series resistance of the transistors may be achieved. In sophisticated applications, however, the total resistance of transistors may no longer be determined by the drain and source regions and the channel region, but rather a contact resistivity may increasingly become a dominant factor, since, with the reduction in size of the transistor elements, corresponding contact elements, which are to be understood as conductive elements extending through a dielectric material of a contact level of the semiconductor device, may also have to be accordingly adapted. In particular, the contact resistivity, i.e., the resistance of the transition area from the contact element to the highly doped drain and source areas is typically reduced by forming a metal/silicon compound in the highly doped drain and source regions, which typically provides a lower resistance compared to even very strongly doped silicon material. To this end, appropriate silicidation processes have been developed in which a refractory metal, such as cobalt, titanium and the like, is deposited and subsequently exposed to appropriate elevated temperatures in the range of 350-600° C. in order to initiate a chemical reaction between the silicon material and the refractory metal. The resulting resistance value of the silicon/metal compound strongly depends on the metal species and the process conditions. In recent developments, nickel is used as a preferred candidate for a metal silicide material due to its reduced resistivity compared to, for instance, cobalt silicide and the like. When forming a nickel silicide in the highly doped silicon regions, a nickel layer is typically formed, for instance, by sputter deposition, and a heat treatment on the basis of temperatures in the range of approximately 400° C. is subsequently applied, wherein an exposure to elevated temperatures in the further processing may be suppressed, since, in this case, the nickel silicide previously thermally stabilized on the basis of temperatures as specified above may otherwise exhibit reduced stability and/or increased resistivity.

In a typical process flow, the basic transistor configuration is completed after performing any high temperature processes and, thereafter, the nickel silicide may be formed on the basis of a process strategy as set forth above, wherein any non-reacted nickel material on dielectric surface areas may be efficiently removed on the basis of wet chemical selective etch recipes. Thereafter, the interlayer dielectric material system of the contact level is provided by, for instance, plasma enhanced chemical vapor deposition (CVD) techniques, in which process temperatures may typically be adjusted to a level that does not unduly affect the previously formed metal silicide. Thereafter, contact openings are formed in the interlayer dielectric material and are subsequently filled with an appropriate contact material, such as tungsten, which is typically provided, in combination with appropriate barrier materials, such as titanium and titanium nitride, on the basis of a thermally activated CVD process, wherein, also in this case, the applied process temperatures are compatible with the previously formed nickel silicide material.

Recently, sophisticated process strategies have been developed in which elevated temperatures may have to be applied in a very late manufacturing stage, i.e., after forming at least a part of the contact level, wherein these temperatures may not be compatible with the metal silicide formed in the doped semiconductor areas. For example, in sophisticated semiconductor devices, high-k metal gate electrode structures are frequently provided in order to overcome the limitations imposed by conventional silicon/polysilicon-based gate electrode structures. To this end, high-k dielectric materials, such as hafnium oxide, hafnium silicon oxide, zirconium oxide and the like, may be provided as a gate dielectric material, possibly in combination with a very thin conventional silicon oxide-based material, in order to reduce the gate leakage currents for a required capacitive coupling between the gate electrode and the channel region. Moreover, metal-containing electrode materials may be provided in combination with the high-k dielectric material in order to endow these sophisticated gate electrode structures with superior conductivity and adjust an appropriate work function. Since, generally, fabrication of sophisticated high-k metal gate electrode structures requires a plurality of very complex process strategies, in some approaches, critical process steps, such as the incorporation of superior electrode materials, may be performed in a very late manufacturing stage, while the actual patterning and, thus, adjusting of the critical dimensions of the gate electrode structures may be accomplished on the basis of well-established gate materials, such as silicon dioxide and polysilicon. After completing the basic transistor configuration, in these approaches, the interlayer dielectric material, or at least a portion thereof, is typically provided and the polysilicon of the gate electrode structures is then exposed on the basis of a removal process in order to enable the removal of the polysilicon material and the replacing thereof with appropriate metal-containing electrode materials. In some of these so-called replacement gate approaches, the incorporation of appropriate metal-containing materials may be associated with high temperature processes, for instance for appropriately incorporating work function metal species and the like, wherein the applied process temperatures may frequently not be compatible with the formation of a nickel silicide in an early manufacturing stage.

Consequently, process strategies have been developed in which the contact resistivity may be reduced in a later manufacturing stage, for instance after replacing polysilicon material by metal-containing electrode materials in replacement gate approaches, wherein a nickel silicide may be formed locally within the contact openings by forming a nickel layer in the contact opening and initiating the silicidation in accordance with well-established nickel silicide process recipes, followed by the removal of any excess metal. Thereafter, the contact metal may be formed by well-established process strategies, as discussed above.

As previously described, the overall transistor performance may significantly depend on the total resistance and, in particular, on the contact resistivity and the resistance of the contact elements. By forming the nickel silicide area on the basis of the contact openings, the formation of the metal silicide may be substantially restricted in the doped semiconductor regions to an area as defined by the corresponding contact elements, which may result in an inferior overall conductivity of the highly doped semiconductor regions compared to process strategies in which the nickel silicide areas are formed in an early manufacturing stage. In some approaches, the reduction in size of the metal silicide regions may at least be partially compensated for by providing appropriately dimensioned contact elements, for instance in the form of trenches, which, however, may not necessarily be compatible with the design requirements for certain transistors. For example, the provision of contact trenches may influence the overall stress conditions, when highly stressed interlayer dielectric materials are to be provided. Furthermore, as also previously discussed, contact openings of substantially square-shaped dimension may suffer from an increased resistance, since typically sophisticated barrier materials, such as titanium and titanium nitride, may have to be provided in combination with sophisticated tungsten CVD techniques, wherein the thickness of the conductive barrier materials may not be reduced in the same manner as the lateral dimensions of the contact elements have to be reduced in order to comply with the overall design requirements. Since the resistance of the conductive barrier material is typically significantly higher compared to the actual tungsten material, upon further reducing the lateral size of contact elements that may not be provided in the form of contact trenches due to design requirements, an over-proportional increase of the contact resistance is observed. In combination with the late formation of the nickel silicide, which results in a significantly reduced nickel silicide area in the highly doped silicon regions, the overall resistance of sophisticated transistor elements may not be reduced as desired, even though highly complex high-k metal gate electrode structures are provided.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques and semiconductor devices in which superior contact resistivity may be achieved on the basis of a very efficient process flow, while the sensitive metal silicide may be provided in a late manufacturing stage. To this end, the refractory metal for forming the metal silicide areas in highly doped semiconductor regions, such as a nickel material, may be formed in the contact openings, which may have any appropriate lateral size in accordance with design requirements. Thereafter, the contact material may be deposited and may be treated at elevated temperatures, which in turn may initiate the silicide formation in the highly doped semiconductor region. In some illustrative embodiments disclosed herein, the deposition of the contact material, for instance in the form of tungsten, may be accomplished on the basis of a thermally activated deposition process, wherein the process temperature may, at the same time, provide appropriate thermal conditions for initiating the silicidation process. Consequently, a very efficient overall process flow may be obtained, wherein, in some illustrative embodiments disclosed herein, the refractory metal used for forming the metal silicide material may also act as an efficient barrier material when, for instance, a direct contact of a deposition atmosphere for forming the contact material with the dielectric material may be considered inappropriate. Since typically the refractory metal may have a superior electrical conductivity compared to conventionally used barrier materials, such as titanium and titanium nitride, in total, superior performance of the contact elements may be achieved.

One illustrative method disclosed herein comprises forming a contact opening in a dielectric material of a contact level of a semiconductor device, wherein the contact opening connects to a doped semiconductor region. The method further comprises forming a refractory metal layer on inner surface areas of the contact opening and on a portion of the doped semiconductor region exposed by the contact opening. Moreover, a contact material is formed on the refractory metal layer and a heat treatment is performed in order to form a metal silicide in the doped semiconductor region in the presence of at least a portion of the contact material.

A further illustrative method disclosed herein comprises forming a contact opening in a dielectric material of a semiconductor device, wherein the contact opening exposes a portion of a doped semiconductor region. The method further comprises forming a first metal layer in the contact opening. The method further comprises performing a thermally activated deposition process so as to form a second metal layer in the contact opening and to form a semiconductor/metal compound from the first metal layer in the portion of the doped semiconductor region.

One illustrative semiconductor device disclosed herein comprises a doped semiconductor region formed in a semiconductor layer of the semiconductor device. The semiconductor device further comprises a contact level formed above the semiconductor layer and comprising a dielectric material and a contact element formed in the dielectric material. The contact element has a lower end portion in contact with the doped semiconductor region and comprising a first metal species that forms a metal/semiconductor compound. The contact element further comprises a second metal species provided in a central portion of the contact element and being separated from the dielectric material by the first metal species.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d schematically illustrate cross-sectional views of a semiconductor device during various manufacturing stages in forming a metal silicide and a contact element in a late manufacturing stage on the basis of a common process sequence, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides semiconductor devices and manufacturing techniques in which the contact resistivity of doped semiconductor regions, such as drain and source regions of field effect transistors and the like, may be reduced by forming a metal silicide, such as a nickel silicide material, in a late manufacturing stage, i.e., after providing at least a portion of an interlayer dielectric material of a contact level, wherein, however, contrary to conventional approaches, the metal species for the metal silicide and the metal species for the contact elements may be thermally activated in a common heat treatment, for instance, in some illustrative embodiments, by using appropriate process temperatures during a thermally activated deposition process for providing the metal species for the contact elements, in order to initiate the formation of a metal silicide in a portion of the highly doped semiconductor region that is exposed by the contact openings. Consequently, in some illustrative embodiments, the metal species, such as the nickel material, may act as one component for a metal silicide compound and may additionally provide a barrier function, thereby allowing omitting one or more barrier materials, which are typically used in conventional strategies, or at least any such barrier materials may be provided with a significantly reduced thickness, thereby contributing to a superior conductivity of the resulting contact element.

Thus, the principles disclosed herein may be advantageously applied in the context of sophisticated process strategies, for instance in replacement gate approaches, in which elevated temperatures may be required for adjusting the final characteristics of sophisticated high-k metal gate electrode structures.

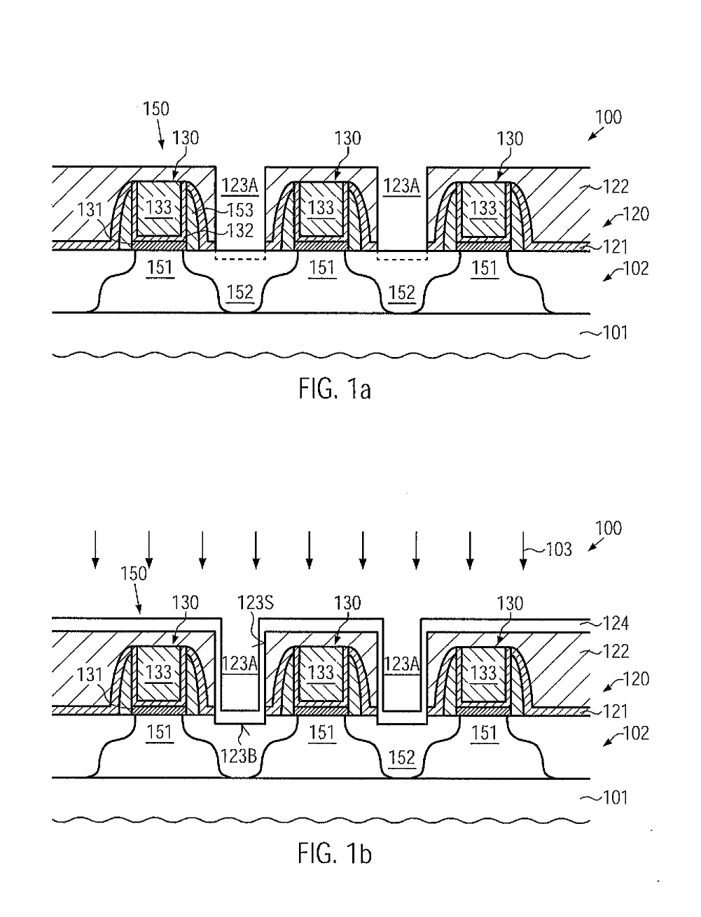

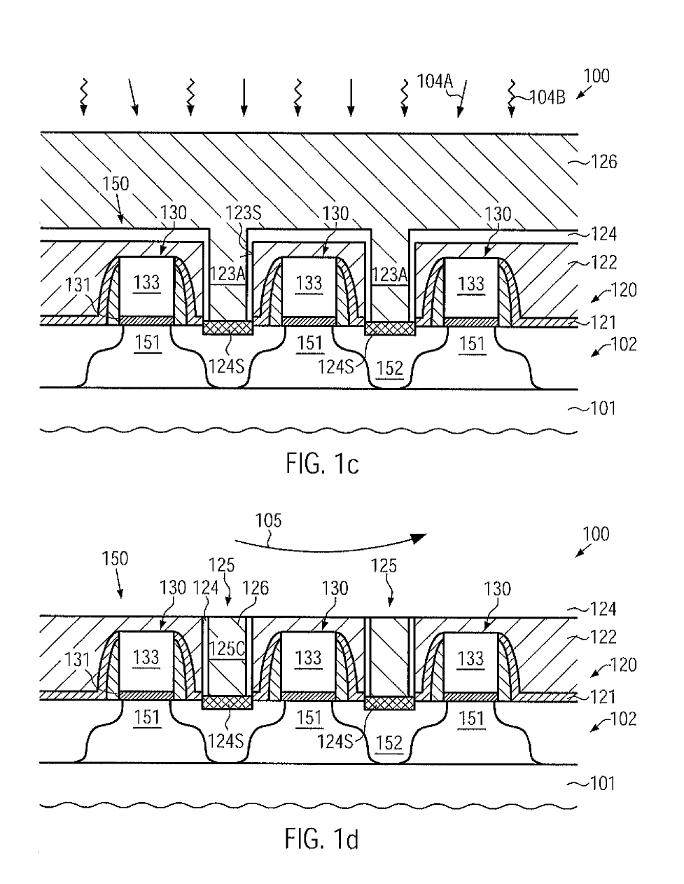

FIG. 1a schematically illustrates a cross-sectional view of a semiconductor device 100 in an advanced manufacturing stage. As illustrated, the device 100 may comprise a substrate 101 and a semiconductor layer 102, which typically comprises a significant amount of silicon material, the conductivity of which may be locally increased on the basis of a metal silicide material still to be formed. The semiconductor layer 102 and the substrate 101 may represent a silicon-on-insulator (SOI) architecture or a bulk configuration, in which the layer 102 may represent an upper portion of a crystalline silicon-based semiconductor material of the substrate 101. Moreover, a plurality of circuit elements 150 may be formed in and above the semiconductor layer 102 in accordance with design requirements. To this end, typically, the semiconductor layer 102 may comprises a plurality of active regions in combination with isolation regions, such as shallow trench isolations and the like, which may, thus, laterally delineate corresponding active regions. For convenience, any such isolation structures are not shown in FIG. 1a. Furthermore, the portion of the semiconductor layer 102 illustrated in FIG. 1a is to be understood as representing an active region, which generally represents a semiconductor region in which highly doped areas are to be provided, for instance, in the form of drain and source regions 152, when the circuit elements 150 represent field effect transistors. It should be appreciated, however, that the regions 152 may represent any doped semiconductor regions in the layer 102, which may locally receive a metal silicide in a later manufacturing stage in order to reduce the overall series resistance and improve contact resistivity.

Moreover, in some illustrative embodiments, the circuit elements 150, when representing sophisticated field effect transistors, may comprise a gate electrode structure 130, which may control the current flow in a channel region 151, as is also discussed above. In the embodiment shown, the gate electrode structures 130 represent sophisticated high-k metal gate electrode structures comprising a gate dielectric material 131, which may comprise a high-k dielectric component, such as hafnium oxide, hafnium silicon oxide, zirconium oxide and the like, possibly in combination with a thin conventional dielectric material, such as silicon dioxide, silicon oxynitride and the like. Furthermore, a metal-containing electrode material 133, such as aluminum, an aluminum alloy and the like, may be provided, possibly in combination with one or more additional metal-containing material layers 132, for instance provided in the form of titanium nitride, tantalum nitride, tantalum and the like, while also specific work function adjusting metal species, such as lanthanum, aluminum and the like, may be provided in the layer 132 and/or in the layer 131, depending on the overall process strategy. It should be appreciated that a high-k dielectric component of the layer 131 may be formed only at the bottom of the gate electrode structure 130, while, in other cases; the high-k dielectric material may also be formed on sidewalls of the gate electrode structure 130, depending on the specific process strategy. Typically, the gate electrode structures 130 may have a gate length, i.e., in FIG. 1a, the horizontal extension of the materials 131 and 133, of 50 nm and significantly less. It should be appreciated, however, that other transistor architectures, such as three-dimensional field effect transistors and the like, may also be provided in combination with sophisticated metal gate electrode structures, depending on the overall configuration of the semiconductor device 100. Moreover, if required, a sidewall spacer structure 153 may be formed on sidewalls of the gate electrode structure 130.

As illustrated, an interlayer dielectric material 120 may be provided so as to at least laterally enclose the gate electrode structures 130, while, in the embodiment shown, a portion of the interlayer dielectric material 120 may also be formed above the gate electrode structures 130. The interlayer dielectric material 120 may represent any appropriate material or material system in order to provide the required passivating characteristics. For example, frequently, at least two different materials may be provided, for instance in the form of a silicon nitride material 121 and a silicon dioxide material 122. It should be appreciated, however, that any other dielectric materials may be applied, depending on the overall requirements with respect to a contact level of the semiconductor device 100. Furthermore, in the manufacturing stage shown, contact openings 123A may be formed in the dielectric material 120 and may, thus, in the embodiment shown, extend through the layers 122 and 121 so as to connect to the highly doped semiconductor regions 152, such as drain and source regions of transistors. The contact openings 123A may have any lateral shape in accordance with the overall design requirements. For example, the contact openings 123A may be provided in the form of trenches, which may extend along a width direction, i.e., in FIG. 1a, the direction perpendicular to the drawing plane of FIG. 1a, in accordance with requirements with respect to overall contact resistivity and the like, as is also previously discussed. For example, when provided in the form of trenches, the openings 123A may extend along an entire width of the highly doped region 152, thereby providing a maximum surface area in the doped region 152 that is exposed by the contact openings 123A and that is, thus, available for a subsequent formation of a metal silicide. In other cases, the contact openings 123A may have any other appropriate form, for instance these openings may have a restricted extension in the width direction, i.e., perpendicular to the drawing plane of FIG. 1a, if required, for instance in order to substantially not interfere with other concepts, for instance when one or both of the materials 121, 122 are provided with a high internal stress level so as to increase the charge carrier mobility, for instance, in the channel region 151. For example, in this case, the lateral extension of the openings 123A in a direction perpendicular to the drawing plane of FIG. 1a may be of comparable size as the extension in the direction of the gate length, i.e., along the horizontal direction in FIG. 1a. For example, in this direction, the contact openings 123A may have a size of 50 nm and less.

The semiconductor device 100 as illustrated in FIG. 1a may be formed on the basis of any appropriate process strategy. For example, active regions, such as the portion of layer 102 as shown in FIG. 1a, may be defined in the layer 102 on the basis of isolation regions (not shown), which may be formed on the basis of well-established trench isolation techniques. Thereafter, the gate electrode structures 130 may be formed on the basis of conventional materials, such as silicon dioxide and polysilicon, and may be patterned in accordance with sophisticated lithography and etch techniques. In some approaches, a high-k dielectric material, possibly in combination with a metal-containing cap material, may already be implemented into the gate electrode structures 130 in an early manufacturing phase. Thereafter, the highly doped regions 152 may be formed, for instance by implantation in combination with sophisticated masking regimes, while using the gate electrode structures 130 and the sidewall spacer structure 153 as an efficient implantation mask. After any high temperature processes for annealing the doped regions 152 and, thus, adjusting the final dopant profile therein, the interlayer dielectric material 120, for instance in the form of the material layers 121 and 122, may be provided on the basis of any appropriate deposition technique. Next, the material 120 may be planarized by performing a removal process, such as a chemical mechanical polishing (CMP) process and the like, and finally a top surface of polysilicon material may be exposed. In a subsequent highly selective etch process, the polysilicon material may be removed, possibly in combination with a dielectric material, or a portion thereof, depending on the overall process strategy. Thereafter, a high-k dielectric material may be deposited, followed by one or more metal-containing electrode materials, such as the layers 132 and 133, wherein, in some approaches, high temperature processes may have to be applied, including process temperatures of approximately 500° C. and higher, in order to establish the desired electronic characteristics of the gate electrode structures 130, for instance in terms of work function and, thus, threshold voltage and the like. If required, an additional material layer may be deposited, for instance in the form of silicon dioxide, silicon nitride and the like, after removing an excess portion of the sophisticated gate materials. Thereafter, sophisticated lithography and patterning strategies may be applied in order to form the contact openings 123A by applying well-established process strategies, thereby forming the contact openings 123A so as to extend to and into the highly doped semiconductor regions 152.

FIG. 1b schematically illustrates the semiconductor device 100 during a deposition process 103 in order to provide a layer of refractory metal 124 within the contact openings 123A and in particular at a bottom 123B of the contact openings 123. In some illustrative embodiments, the refractory metal 124 may comprise nickel in order to provide a highly conductive metal silicide in the doped regions 152. The deposition process 103 may be performed as a sputter deposition process, which may per se provide superior control of film thickness, while also enabling an efficient precleaning of the exposed surface areas by a sputter precleaning phase during the process 103. Moreover, during the sputter deposition, an appropriate DC (direct current) or RF (radio frequency) bias may be established in order to provide superior directionality of moving ionized target atoms, which may, thus, efficiently deposit at the bottom 123B of the opening 123A. At the same time, sidewall surface areas 123S in the opening 123A may be covered by the material of the layer 124, wherein, if required, the deposition process 103 may include a re-sputter process in order to redistribute, at least to a certain degree, material formed on the bottom 123B to upper sidewall areas in order to provide reliable coverage of any of the surface areas 123S. Consequently, in this case, the refractory metal 124 may reliably cover any exposed surface areas of the material 120 prior to the deposition of an actual contact material, such as tungsten, when a direct contact of this material or a process atmosphere required for the deposition of this material is considered inappropriate. Consequently, a thickness of the material 124 within the contact openings 123A may be readily controlled so as to provide sufficient material at the bottom 123B in view of forming a metal silicide in the doped semiconductor regions 152 with a desired thickness, while at the same time a reliable coverage of the sidewall surface areas 123S may be guaranteed. In this manner, the refractory metal 124 may also act as an efficient barrier material.

FIG. 1c schematically illustrates the semiconductor device 100 in a further advanced manufacturing stage. As illustrated, a layer of contact material 126, in some illustrative embodiments in the form of tungsten, may be formed above the dielectric material 120 and within the contact openings 123A. In the embodiment shown, the material 126 may be formed directly on the refractory metal layer 124, while, in other cases, an additional conductive barrier material (not shown) may be provided, if the barrier effect of the material 124 within the openings 123A is considered insufficient. In this case, however, the optional barrier material may be applied with a reduced layer thickness compared to conventional strategies, since even with a reduced thickness of the optional barrier material in combination with the material 124, a sufficient integrity of the material 121 and 122 may be accomplished.

The material layer 126 may be provided on the basis of a deposition process 104A, which, in some illustrative embodiments, may represent a thermally activated deposition process. In this case, appropriate process temperatures may be established during a heat treatment, such as a heat treatment 104B, which in this case may be part of the deposition sequence. For example, tungsten is frequently deposited on the basis of chemical vapor deposition using hexafluoride (WF₆), which is thermally activated in a first step on the basis of silane (SiH₄), wherein elevated temperatures in the range 380-450° C. may be applied. The tungsten hexafluoride may then be converted into tungsten on the basis of hydrogen, wherein the refractory metal 124, possibly in combination with an optional barrier material, may suppress a direct contact of the reactive component with sensitive materials, such as silicon dioxide. Consequently, tungsten may be efficiently deposited, wherein the elevated process temperatures may at the same time initiate silicon and metal interdiffusion in the highly doped semiconductor region 152 at the bottom of the contact openings 123A. Consequently, a metal silicide 124S may form, such as a nickel silicide, driven by the elevated temperatures during the deposition of the material 126.

It should be appreciated that typically metal silicide formation in the doped semiconductor region 152 and deposition of a certain amount of the material 126 may concurrently occur, wherein the silicidation process may be completed upon consuming any of the refractory metal at the bottom of the openings 123A and/or by reducing a process temperature, for instance after depositing the material 126.

In other illustrative embodiments, the material 126 may be deposited on the basis of any other appropriate deposition process, which may enable a substantially void-free deposition of the contact material 126 in the openings 123A, while the heat treatment 104B may be performed immediately prior to or after the deposition of the material 126.

FIG. 1d schematically illustrates the semiconductor device 100 in a further advanced manufacturing stage. As shown, a removal process 105 may be applied in order to remove any excess portions of the material layers 126 and 124 (FIG. 1c). To this end, CMP processes, etch processes and the like may be applied in order to provide electrically insulated contact elements 125 comprising at a lower end portion in the form of the metal silicide compound 124S, while a central portion 125C may comprise the refractory metal 124 and the contact material 126. In the embodiment shown, the contact material 126, such as tungsten, may be separated from the dielectric material or materials 120 by the refractory metal 124, while, in other illustrative embodiments (not shown), an additional optional conductive barrier material may be provided between the refractory metal layer 124 and the contact material 126.

As a result, the present disclosure provides semiconductor devices and manufacturing techniques in which contact elements may be provided on the basis of a very efficient process flow, in which a metal species for forming a metal silicide and a metal species of the contact material may be provided concurrently within the contact openings upon performing a silicidation process, while, in some illustrative embodiments, the silicidation may be initiated on the basis of a thermally activated deposition process for forming the contact material. Consequently, a metal silicide may be formed in a late manufacturing stage, while at the same time reducing the total resistance of the contact elements by using a refractory metal as an efficient barrier material. The process sequence may be efficiently applied to forming sophisticated gate electrode structures on the basis of replacement gate approaches.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a contact opening in a dielectric material of a contact level of a semiconductor device, said contact opening connecting to a doped semiconductor region;
forming a refractory metal layer on inner surface areas of said contact opening and on a portion of said doped semiconductor region exposed by said contact opening;
forming a contact material on said refractory metal layer; and
performing a heat treatment for forming a metal silicide in said doped semiconductor region in the presence of at least a portion of said contact material.

2. The method of claim 1, wherein forming said contact material comprises performing a thermally activated deposition process so as to perform said heat treatment at least concurrently with said deposition process.

3. The method of claim 2, wherein forming said contact material comprises forming a tungsten material.

4. The method of claim 1, wherein forming a refractory metal layer comprises depositing a nickel layer.

5. The method of claim 1, wherein a process temperature of said heat treatment is in the range of 380-450° C.

6. The method of claim 1, further comprising forming a metal-containing gate electrode structure prior to forming said contact opening.

7. The method of claim 6, wherein said metal-containing gate electrode structure is formed after forming said dielectric material of said contact level.

8. The method of claim 1, further comprising removing an excess portion of said contact material and said refractory metal by performing a common removal process.

9. The method of claim 1, wherein forming said contact opening comprises forming a trench in said dielectric material.

10. A method, comprising:
forming a contact opening in a dielectric material of a semiconductor device, said contact opening exposing a portion of a doped semiconductor region;
forming a first metal layer in said contact opening; and
performing a thermally activated deposition process so as to form a second metal layer in said contact opening and to form a semiconductor/metal compound from said first metal layer in said portion of said doped semiconductor region.

11. The method of claim 10, wherein said first metal layer comprises nickel.

12. The method of claim 10, wherein said second metal layer comprises tungsten.

13. The method of claim 10, wherein performing said thermally activated deposition process is performed at a process temperature of 380-450° C.

14. The method of claim 10, further comprising removing an excess portion of said first and second metal layers by performing a common removal process.

15. The method of claim 10, further comprising forming a high-k metal gate structure adjacent to said semiconductor region prior to forming said contact opening.

16. The method of claim 15, wherein at least an electrode metal of said high-k metal gate electrode structure is provided after forming said dielectric material.

17. A semiconductor device, comprising:
a doped semiconductor region formed in a semiconductor layer of said semiconductor device; and
a contact level formed above said semiconductor layer and comprising a dielectric material and a contact element formed in said dielectric material, said contact element having a lower end portion in contact with said doped semiconductor region and comprising a first metal species forming a metal/semiconductor compound, said contact element further comprising a second metal species provided in a central portion of said contact element and being separated from said dielectric material by said first metal species.

18. The semiconductor device of claim 17, wherein said first metal species comprises nickel.

19. The semiconductor device of claim 18, wherein said second metal species comprises tungsten.

20. The semiconductor device of claim 17, further comprising a high-k metal gate electrode structure.
